(19) United States
(12) Patent Application Publication
(10) Pub. No.: US 2026/0082792 A1
(43) Pub. Date: Mar. 19, 2026

(54) TOUCH DISPLAY MODULE AND DISPLAY MODULE

(71) Applicant: TPK Advanced Solutions Inc., Xiamen (CN)

(72) Inventors: Ren-Yuan YAN, Xiamen City (CN); Ching-Kai Cho, Changhua County (TW); Jia-Jing Chen, Xiamen City (CN)

(21) Appl. No.: 19/324,648

(22) Filed: Sep. 10, 2025

(30) Foreign Application Priority Data
Sep. 19, 2024 (CN) 202411310400.2

(51) Int. Cl. H10K 59/40; G06F 3/044

(52) U.S. Cl. CPC H10K 59/40; G06F 3/0445

(57) ABSTRACT

A touch display module comprises a touch-sensing layer and an organic light-emitting diode display. The touch-sensing layer comprises a plastic substrate, a first metal mesh electrode layer, and a second metal mesh electrode layer. The thickness of the plastic substrate is 10 μm to 400 μm. The plastic substrate has a first refractive index and a second refractive index in different directions, and a difference (birefringence) between the first refractive index and the second refractive index is 0 to 0.0001. The first metal mesh electrode layer is disposed on the first surface. The second metal mesh electrode layer is disposed on a second surface, wherein the second surface is facing away from the first surface. The organic light-emitting diode display is disposed on one side of the touch-sensing layer. The maximum black level luminance of the touch display module is 0.0001 cd/m² to 0.0005 cd/m².

### CROSS-REFERENCE TO RELATED APPLICATION

This application claims priority to China Patent Application 202411310400.2, filed Sep. 19, 2024, which is incorporated herein by reference.

### FIELD OF DISCLOSURE

The present disclosure relates to a touch display module and a display module.

### DESCRIPTION OF RELATED ART

With the development of display technology, organic light-emitting diode (OLED) displays or tandem OLEDs have been gradually introduced and applied to electronic products. For example, OLED displays or tandem OLEDs have been applied to augmented reality (AR)/virtual reality (VR)/mixed reality (MR) glasses, smartwatch, smartphone, tablet personal computer (PC), laptop computer, artificial intelligence personal computer (AI PC), center information display (CID), treadmill, gaming monitor, charging station, smart television (TV), point of sale (POS) machine, video conferencing system, or interactive whiteboard (IWB). The high dynamic range (HDR) is one key index of the field of display technology. For instance, the Video Electronics Standards Association (VESA™) in the U.S. formulated the specification of HDR 500 True Black™, which requires the black level luminance of displays in dark environments to be extremely low, ensuring sufficient contrast between scenes of high luminance and scenes of low luminance. However, during the display panel development process, manufacturers often face the problem that display panels may not satisfy the requirements of the HDR 500 True Black™ specification, as the peak luminance of a display panel becomes affected by the interaction with the touch-sensing layer after the display panel is laminated to the touch-sensing layer. To resolve such a problem, a common practice is to blacken the metal electrode of the touch-sensing layer (for example, plating darker palladium) to overcome the dark-state light leakage problem of silver (Ag) or copper (Cu) metal electrodes caused by the high brightness of the display. Another practice is to modify the voltage value of the circuit so that the black level luminance will meet the requirement. However, the additional adjustment through the blackening process will increase production costs, and many problems remain with the method of adjusting the voltage. For example, if the voltage is too high, power consumption of the display will increase, thereby shortening a service life of the display. Besides, frequent adjustments to the voltage setting may lead to deterioration in the stability of the display panel. China Patent Application No. CN 116027929A discloses a method of reducing light leakage by having an additional deposition of light-absorbing materials in order to meet the standard of black-level luminance. However, this method increases the complexity of the production process, and light-absorbing materials may easily affect the colors of the display panels, causing heat to accumulate near them and thereby compromising the overall stability of the display panels.

### SUMMARY

According to several embodiments of the present disclosure, the touch display module (TDM) comprises a touch-sensing layer and an organic light-emitting diode display. The touch-sensing layer comprises a plastic substrate, a first metal mesh electrode layer, and a second metal mesh electrode layer. A thickness of the plastic substrate is 10 μm to 400 μm. The plastic substrate has a first refractive index and a second refractive index in different directions, and a difference (birefringence, Δn) between the first refractive index and the second refractive index is controlled to be smaller than or equal to 0.0001 (for example, 0 to 0.0001). The first metal mesh electrode layer is disposed on a first surface of the plastic substrate. The second metal mesh electrode layer is disposed on a second surface of the plastic substrate, wherein the second surface faces away from the first surface. The organic light-emitting diode display is disposed on one side of the touch-sensing layer, wherein a peak luminance of the organic light-emitting diode display is at least 390 nits. A maximum black level luminance of the touch display module ranges from 0.0001 cd/m² to 0.0005 cd/m².

In one or several embodiments of the present disclosure, the thickness of the plastic substrate is 10 micrometers (μm) to 40 μm.

In one or several embodiments of the present disclosure, the difference (birefringence, Δn) between the first refractive index and the second refractive index is 0.0000125 to 0.0001.

In one or several embodiments of the present disclosure, the touch-sensing layer further comprises a primer coating layer disposed on the first surface of the plastic substrate, wherein the first surface faces away from the one side of the touch-sensing layer. A refractive index of the primer coating layer is smaller than an average value of the first refractive index and the second refractive index.

In one or several embodiments of the present disclosure, the primer coating layer is disposed between the plastic substrate and the first metal mesh electrode layer. In one or several embodiments of the present disclosure, the primer coating layer is disposed between the plastic substrate and the second metal mesh electrode layer.

In one or several embodiments of the present disclosure, the touch-sensing layer further comprises an optically clear adhesive (OCA) layer. The first surface faces away from the one side of the touch-sensing layer, and a refractive index of the optically clear adhesive layer is smaller than an average value of the first refractive index and the second refractive index.

In several other embodiments of the present disclosure, the display module comprises a plastic substrate and an organic light-emitting diode display. A thickness of the plastic substrate is 10 μm to 400 μm. The plastic substrate has a first refractive index and a second refractive index in different directions, wherein a difference (birefringence, Δn) between the first refractive index and the second refractive index is controlled to be smaller than or equal to 0.0001 (for example, 0 to 0.0001). The organic light-emitting diode display is disposed on one side of the plastic substrate, wherein a peak luminance of the organic light-emitting diode display is at least 390 nits. A maximum black level luminance of the display module ranges from 0.0001 cd/m² to 0.0005 cd/m².

In one or several embodiments of the present disclosure, the thickness of the plastic substrate is 10 μm to 40 μm.

In one or several embodiments of the present disclosure, the difference (birefringence, Δn) between the first refractive index and the second refractive index is 0 to 0.0001.

In one or several embodiments of the present disclosure, a surface roughness of the plastic substrate is 2 angstrom (Å) to 200 Å.

In one or several embodiments of the present disclosure, the display module further comprises an optically clear adhesive layer disposed on the one surface facing away from the side of the plastic substrate, wherein a refractive index of the optically clear adhesive layer is smaller than an average value of the first refractive index and the second refractive index.

In one or several embodiments of the present disclosure, the display module further comprises a primer coating layer disposed between the plastic substrate and the optically clear adhesive layer, wherein a refractive index of the primer coating layer is smaller than the average value of the first refractive index and the second refractive index.

In one or several embodiments of the present disclosure, the refractive index of the primer coating layer is smaller than the refractive index of the optically clear adhesive layer.

In one or several embodiments of the present disclosure, a difference between the refractive index of the primer coating layer and the refractive index of the plastic substrate is larger than a difference between the refractive index of the optically clear adhesive layer and the refractive index of the plastic substrate.

In one or several embodiments of the present disclosure, a thickness of the primer coating layer is 0.01 μm to 5 μm.

According to several other embodiments of the present disclosure, the touch display module comprises a touch-sensing layer and an organic light-emitting diode display. The touch-sensing layer comprises a plastic substrate, a first-touch electrode layer, and a second-touch electrode layer. A thickness of the plastic substrate is 10 μm to 400 μm. The plastic substrate has a first refractive index and a second refractive index in different directions, wherein the difference between the first refractive index and the second refractive index is controlled to be smaller than or equal to 0.0001 (for example, 0 to 0.0001). The first touch electrode layer is disposed on the upper surface or the lower surface of the plastic substrate, and the second touch electrode layer is disposed on the upper surface or the lower surface of the plastic substrate. The organic light-emitting diode display is disposed on one side of the touch-sensing layer, wherein a peak luminance of the organic light-emitting diode display is at least 390 nits. A maximum black level luminance of the touch display module ranges from 0.0001 cd/m² to 0.0005 cd/m².

In one or several embodiments of the present disclosure, the thickness of the plastic substrate is 10 μm to 40 μm.

In one or several embodiments of the present disclosure, the difference between the first refractive index and the second refractive index is 0.0000125 to 0.0001.

In one or several embodiments of the present disclosure, the touch-sensing layer further comprises two primer coating layers disposed on the upper surface and the lower surface of the plastic substrate, respectively, wherein refractive indices of the two primer coating layers are smaller than an average value of the first refractive index and the second refractive index.

In one or several embodiments of the present disclosure, the touch-sensing layer further comprises two optically clear adhesive layers disposed on the upper surface and the lower surface of the plastic substrate. Refractive indices of the two optically clear adhesive layers are smaller than an average value of the first refractive index and the second refractive index.

According to the aforementioned embodiments of the present disclosure, light rays pass through the plastic substrate with a smaller phase retardation by adjusting the thickness of the plastic substrate and controlling the biaxial refractive index difference (i.e., difference) of the plastic substrate. Therefore, all light rays propagate along the same path through the plastic substrate substantially. Hereby, most light rays are directly emitted from the bright state area, and the remaining small amount of light rays, not emitted from this area, undergo multiple instances of total reflection, which consumes energy. As a result, the probability that light rays emitted from the dark state area is reduced so that the dark-state light leakage problem is solved.

### BRIEF DESCRIPTION OF THE DRAWINGS

To better understand the aforementioned objective and other objectives, novel features, advantages, and embodiments of the present disclosure, relevant diagrams are provided as follows.

FIG. 1 is a schematic side view of a touch display module according to some embodiments of the present disclosure.

FIG. 2 is a schematic side view of a touch display module from the prior art.

FIG. 3 is a schematic side view of diagram of a touch display module according to several embodiments of the present disclosure.

FIG. 4A is a schematic diagram of the upward view of a window pattern of a checkerboard (black and white patches) displayed by the touch display module according to several embodiments of the present disclosure.

FIG. 4B is a schematic diagram of a setting for measuring the black level luminance of the touch display module, as described in several embodiments of the present disclosure.

FIG. 5 is a schematic side view of diagram of a touch display module viewed from the side, according to several other embodiments of the present disclosure.

### DETAILED DESCRIPTION

A plurality of embodiments of the present disclosure will be disclosed below with reference to drawings. For the purpose of clear illustration, many details in practice will be provided together with the following descriptions. However, these detailed descriptions in practice are for illustration only and shall not be interpreted to limit the scope, applicability, or configuration of the present disclosure in any way. For better illustration, the dimensions of each component in the drawing are not scaled to the actual size. Furthermore, opposite terms, such as “lower” and “upper,” are used in this specification to describe the relations of a component with another component. As illustrated in the figures, the purpose of opposite terms is to cover components of different directions in addition to the direction that is illustrated. The terms “first” and “second” in the specification and claims are used to specify different components or to distinguish different embodiments or ranges. They shall not be interpreted as indicating the highest or lowest value to limit the quantity of the component, the manufacturing sequence, or the sequence of component installation.

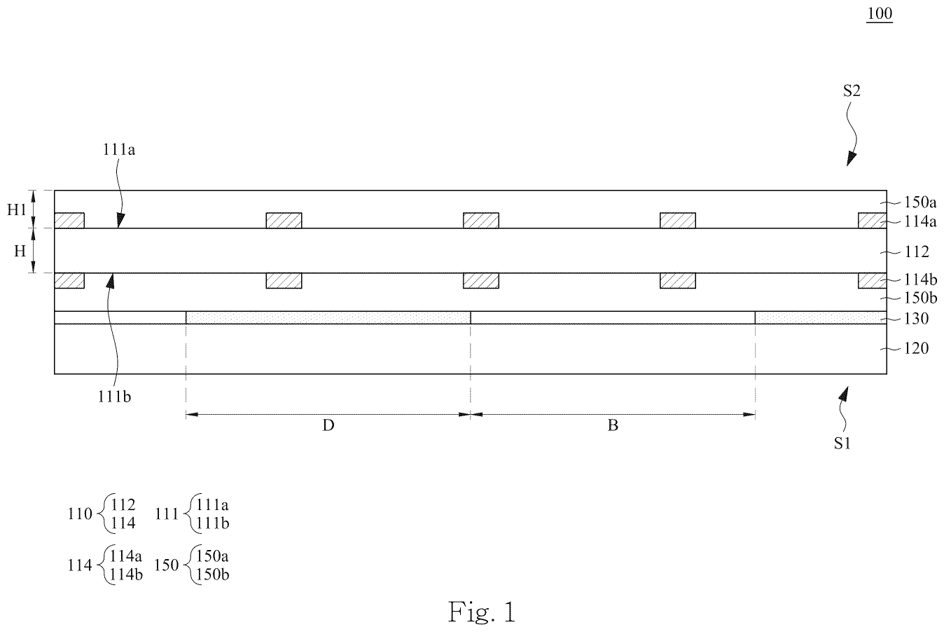

Please refer to FIG. 1, which is a schematic diagram of a touch display module 100 viewed from the side, according to several embodiments of the present disclosure. The touch display module 100 comprises a touch-sensing layer 110 and an organic light-emitting diode display 120. The organic light-emitting diode display 120 is disposed on one side S1 of the touch-sensing layer 110. In one or several embodiments, the peak luminance of the organic light-emitting diode display 120 is at least 390 nits (for example, 400 nits to 600 nits or 700 nits to 1600 nits). For embodiments requiring higher luminance, the peak luminance of the organic light-emitting diode display 120 is at least 700 nits (for example, 750 nits) or at least 800 nits (for example, 850 nits). The method for measuring the peak luminance of the organic light-emitting diode display 120 will be explained in further detail later. In one or more embodiments, the touch display module 100 also comprises a light-shading layer 130 disposed between the touch-sensing layer 110 and the organic light-emitting diode display 120. The light-shielding layer 130 may block light emitted from the organic light-emitting diode display 120 and further control the brightness of the bright state and dark state in different areas of the touch display module 100. Please note that in several other embodiments, apart from using the aforementioned physical methods for blocking light to control the bright state and dark state partially, another method for controlling of the bright state and dark state of the touch display module 100 is to divide the organic light-emitting diode display 120 into multiple independent light-emitting sections in conjunction with driver circuits to precisely control the electrical current of every light-emitting section.

The touch-sensing layer 110 of the present disclosure comprises a plastic substrate 112 and an electrode layer 114, wherein the electrode layer 114 is disposed on the surface 111 of the plastic substrate 112 and corresponds to the visible area disposed on the touch display module 100. In one or several embodiments, the electrode layer 114 has a double-sided electrode structure. For example, as shown in FIG. 1, the electrode layer 114 with a double-sided electrode structure comprises a first electrode layer 114a and a second electrode layer 114b, wherein the first electrode layer 114a is disposed on the first surface 111a (upper surface) of the plastic layer 112 facing away from the side S1 of the touch-sensing layer 110. In contrast, the second electrode layer 114b is disposed on the second surface 111b (lower surface) of the plastic substrate 112 facing the side S1 of the touch-sensing layer 110, and the second surface 111b is facing away from the first surface 111a. In other words, the first electrode layer 114a and the second electrode layer 114b are disposed on surfaces at opposite sides of the plastic substrate 112, respectively. In another example, the first electrode layer 114a and the second electrode layer 114b of the electrode layer 114 with a double-sided electrode structure are disposed on the same side of the plastic substrate 112 (for example, toward the side S2 facing away from the side S1). The first electrode layer 114a and the second electrode layer 114b are separated by an insulating layer (not shown in the figure) disposed therebetween. In other words, the first electrode layer 114a and the second electrode layer 114b are disposed on the same surface (for example, the first surface 111a) of the plastic substrate 112 and are located on two opposite surfaces of the insulating layer, respectively. In several other embodiments, the electrode layer 114 has a single-sided electrode structure (not shown in the figure) or a bridge type single-sided electrode structure (not shown in the figure) (embodiments of bridge type single-sided electrode structures are disclosed in U.S. Pat. Nos. 8,217,902B2, 8,081,169B2, and 9,606,675B2, which are incorporated herein by reference).

In one or several embodiments of the present disclosure, the electrode layer 114 is a metal mesh electrode layer. More specifically, the first electrode layer 114a and the second electrode layer 114b may be formed individually by a plurality of thin metal wires (not shown in the figure) arranged periodically and may be referred to as a first metal mesh electrode layer and a second metal mesh electrode layer, respectively, in the present disclosure. In one or several embodiments, materials of the electrode layer 114 may be transparent conductive materials including but not limited to, for example, silver nanowire, nano conductive material, indium tin oxide (ITO), indium zinc oxide (IZO), antimony tin oxide (ATO), Sb-doped zinc oxide (SZO), carbon nanotubes (CNT), graphene, or other suitable transparent conductive materials made into metal thin wires. In preferable embodiments, materials of the electrode layer 114 include silver halide materials (such as silver bromide (AgBr), silver chloride (AgCl), silver iodide (AgI), or silver fluoride (AgF)) or copper metal (electroless copper plating or copper foil etching processes) for metal thin wires. Another suitable conductive material that has better light absorption may be made into metal thin wires. Using the aforementioned materials, the dark-state light leakage problem of the touch display module 100 may be improved (further descriptions will be provided later).

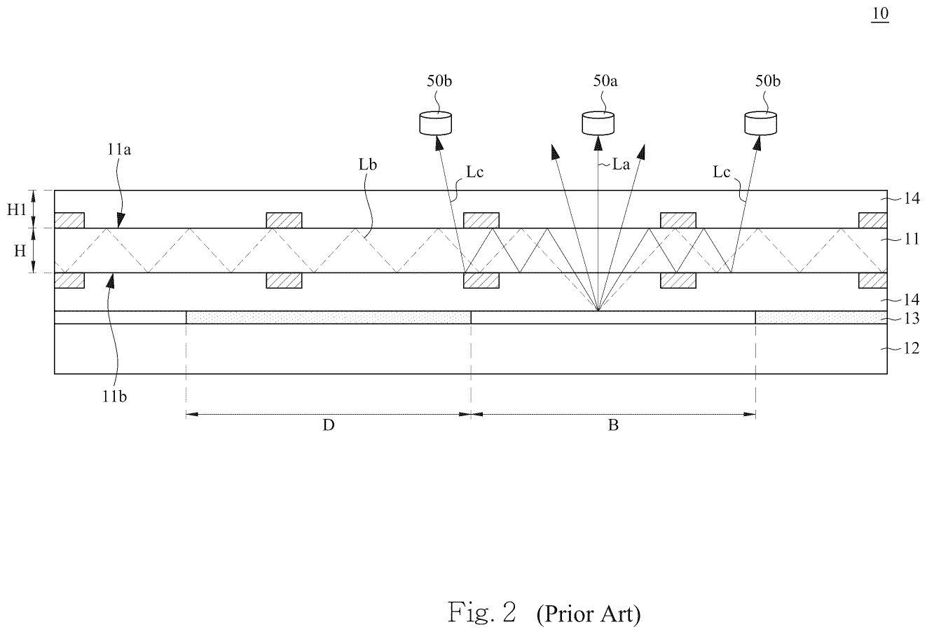

Please refer to FIG. 2, which is a schematic diagram of a touch display module 10 from the side view of the prior art. The touch display module 10 comprises a touch-sensing layer 11, an organic light-emitting diode display 12, and a light-shielding layer 13, wherein opposite surfaces 11a and 11b of the touch-sensing layer 11 comprise one or more layers of functional layers 14. When light rays are emitted from the organic light-emitting diode display 12, the portion of light rays that are not blocked by the light-shielding layer 13 penetrate the touch-sensing layer 11 and are emitted directly from the bright state area B (for example, light ray La). In contrast, the portion of light rays that do not penetrate the touch-sensing layer 11 (for example, light ray Lb) undergo multiple times of total reflection and are expected to remain within the touch-sensing layer 11. Therefore, it is expected to detect light in the bright state area B of the touch display module 10. Light will not be detected in the dark state area D. However, in reality, due to impact from the material of the touch-sensing layer 11 (for example, difference (birefringence, Δn) of the materials), the refractive index of the touch-sensing layer 11 is not a single value and the refractive index thereof is not stable. An unstable refractive index causes the light rays within the touch-sensing layer 11 to have different scale of deflection and further lead to phase retardation. Especially, the angle of incidence in areas of the touch-sensing layer 11, which have a lower refractive index, may be likely larger than the critical angle of total reflection. Therefore, the light ray is refracted out (for example, light ray Lc) and causes unexpected light-emitting phenomena in the dark state area D of the touch display module 10. That phenomena is referred to as dark-state light leakage. More specifically, as shown in FIG. 2, the detector 50a detects light rays in the bright state area B, and the detector 50b may also detect light rays in the dark state area D due to the effect of difference (birefringence, Δn) of the material of the touch-sensing layer 11.

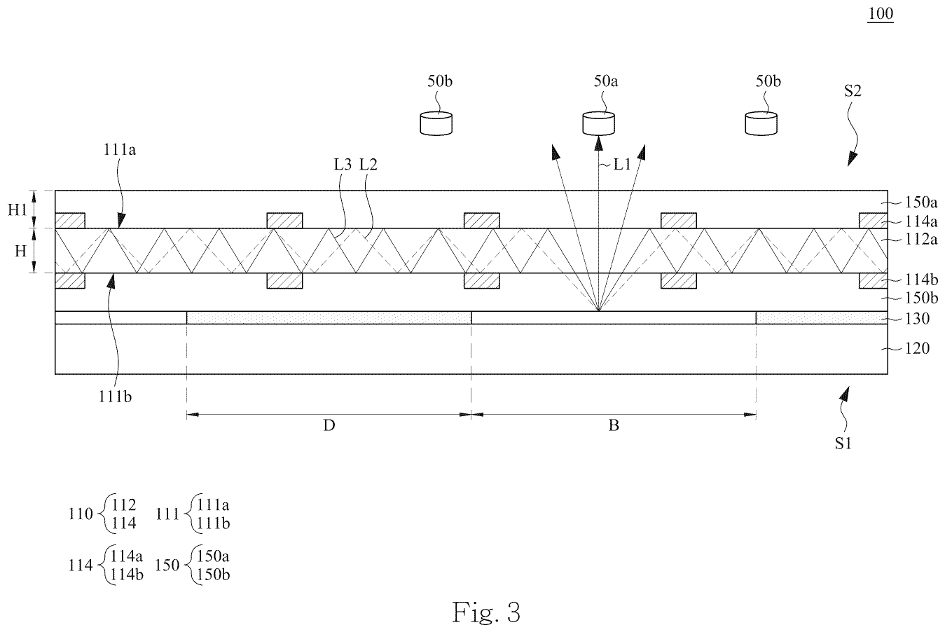

Comparatively, please refer to FIG. 3, which is a side view schematic diagram of a touch display module 100, according to several embodiments of the present disclosure. The present disclosure ensures satisfying the expected luminance when light rays emit directly from the bright state area B (for example, light ray L1) through at least the design of material properties and thickness of the touch-sensing layer 110. The design of material properties and thickness of the touch-sensing layer 110 also confines light rays that do not emit from the bright state area B (for example, light ray L2, light ray L3) within the touch-sensing layer 11 to achieve total reflection. Due to unexpected light ray does not emit in the dark state area D in order to achieve the expected darkness, the detector 50b will not detect light rays in the dark state area D. Thus, the problem of dark-state light leakage is solved. More specifically, please refer to FIG. 1 and FIG. 3. The present disclosure may reduce phase retardation (R0) of light rays while penetrating the plastic substrate 112 by both the following methods. First, selecting the materials with lower difference (birefringence, Δn) as the material made for the plastic substrate 112 of the touch-sensing layer 110, and second, controlling the thickness H of the plastic substrate 112 are performed. Therefore, lessening the condition of in-plane phase difference and out-of-plane phase difference (these two values of difference are viewed as the key reference data produced when light penetrates the plastic substrate 112) occurred between two polarization directions. In order to prevent dark-state light leakage from happening, the relation between the difference (birefringence, Δn) and the thickness H of the plastic substrate 112 is expressed below in Equation (1):

$$R 0 = Δ n \times H \qquad Eq . ( 1 )$$

For the design of the birefringence (Δn) of the material of the plastic substrate 112, please refer to FIG. 1 and FIG. 3. The selected plastic substrate 112 of the present disclosure has a low difference (birefringence, Δn). Specifically, the plastic substrate 112 has ordinary rays (O-ray) that obey the law of refraction and extraordinary rays (E-ray) that do not obey the law of refraction. The ordinary rays and the extraordinary rays are polarized light propagating along different optic axes (directions). A polarization angle of the optic axes ranges from 80 degrees to 100 degrees, or 85 degrees to 95 degrees, or 89 degrees to 91 degrees. The difference (birefringence, Δn) between the refractive index of the ordinary ray and the refractive index of the extraordinary ray is low. In short, the plastic substrate 112 has a first refractive index and a second refractive index corresponding to the ordinary ray and the extraordinary ray, respectively, and the difference (birefringence, Δn) between the first refractive index and the second refractive index is low. Through such a design, the plastic substrate 112 has a stable and consistent refractive index on every axis. Therefore, when light rays enter the plastic substrate 112 and enter other layers situated above (for example, the first optically clear adhesive layer 150a shown in FIG. 1 and FIG. 3), the light rays (for example, light ray L1) with an incident angle smaller than the critical angle will be emitted directly from the bright state area B. When light rays (for example, light rays L2, L3) have an incident angle larger than the critical angle, the light rays are steadily reflected into the plastic substrate 112 at the same reflection angle, i.e., total reflection. The total reflection occurs multiple times to consume the energy thereof and to significantly reduce the probability of light rays being transmitted to the dark state area D, and reduces the probability of emitting the light rays from the dark state area D. Therefore, the design may effectively solve the problem of dark-state light leakage.

More specifically, the difference (birefringence, Δn) between the first refractive index and the second refractive index of the plastic substrate 112 is 0 to 0.0001 (for example, 0.00002, 0.00004, 0.00006, or 0.00008). In other words, the plastic substrate 112 is nearly without difference (birefringence, Δn). In one or several embodiments, when other optical properties (for example, transmittance) of the materials need to be considered as well, a compromise in the selection of materials with slightly higher difference (birefringence, Δn) is available, as the materials used for the plastic substrate 112 are suitable. For example, the birefringence between the first refractive index and the second refractive index of the plastic substrate 112 may be 0.0000125 to 0.0001. In preferable embodiments, the difference (birefringence, Δn) between the first refractive index and the second refractive index of the plastic substrate 112 is 0. Under such circumstances, the plastic substrate 112 is made of isotropic materials, wherein the refractive index is the same in all directions. For the completely plastic substrate 112, the average value of the first refractive index and the second refractive index of the plastic substrate 112 (that is, the overall refractive index of the plastic substrate 112) is 1.48 to 1.66.

For the design of the thickness H of the plastic substrate 112, please refer to FIGS. 1 and 3. The present disclosure may reduce the probability of light rays emitting from the dark state area D by controlling the thickness H of the plastic substrate 112 within a suitable dimension. More specifically, when the thickness H of the plastic substrate 112 is relatively smaller, given a fixed width in the horizontal direction, the optical path of light rays within the plastic substrate 112 is shorter. Therefore, the number of total reflections that light rays exhibit is relatively larger, so that enough energy of the light rays will be consumed during the process of total reflection, and the probability that light rays are transmitted horizontally to the dark state area D is reduced. Hereby, the probability of light rays emitting from the dark state area D may be reduced, and the problem of dark-state light leakage may be solved effectively. On the other hand, if the thickness H of the plastic substrate 112 is too large, it may lead to problems such as optical distortion, a narrow view angle, or an inability to achieve a lightweight touch display module 100. More specifically, the thickness H of the plastic substrate 112 is designed to be 10 μm to 400 μm (for example, 50 μm, 100 μm, 150 μm, 200 μm, 250 μm, 300 μm, or 350 μm). In the preferable embodiments, the thickness H of the plastic substrate 112 ranges from 10 μm to 40 μm, so as to improve the overall performance of the touch display module 100 and to solve the light leakage problem of dark-state area. For example, the thickness H of the plastic substrate 112 is 15 μm, 20 μm, 25 μm, 30 μm, 35 μm, 36 μm, 37 μm, or 38 μm

In summary, by thinning the thickness H and lowing the difference (birefringence, Δn) of the plastic substrate 112, light rays will have a smaller phase retardation (R0) (as described in Eq. (1) previously) while passing through the plastic substrate 112, therefore causing all light rays to tend to propagate along the same path through the plastic substrate 112. Therefore, the overall optical path of light rays tends to become unified. One partial unified light ray is directly emitted from the bright state area B, and the other partial unified light rays are steadily reflected into the plastic substrate 112 at the same reflection angle. The total reflection occurs multiple times to consume the energy of the other partial unified light rays gradually and to prevent the other partial unified light rays from emitting from the dark state area D. Please note that, through adjusting the difference (birefringence, Δn) and the thickness H of the plastic substrate 112, the present disclosure manages to control the optical path instead of controlling the optical path by directly adjusting the phase retardation (R0) of light rays. Such an approach, as used in the present disclosure, may gain an advantage in several folds. For example, to adjust the phase retardation (R0) of light rays directly requires a change in the positions of the optical elements generally. The process involves mechanical adjustments and may easily cause deviations and instability. In contrast, adjusting the refractive index may generally be implemented by modifying the properties of the material itself of the optical elements (for example, composition or structure) without requiring significant mechanical adjustments. This approach offers better controllability, with more accurate and stable control over optical paths. As another example, adjusting the phase retardation (R0) of light rays directly involves adjusting the angle of incidence, which typically requires the use of a phase retarder with a complex element structure. However, this approach is limited by material properties (for example, liquid crystal or photonic crystal) and has a limited adjustment range. In addition, when light rays pass through the phase retarder, multiple modes may be triggered, leading to an increase in inconsistency and complexity in phase adjustment. Therefore, such a method has difficulty in controlling precision at a fine scale.

Please refer to Table 1, which lists the phase retardation (R0) and thickness H of several materials (Materials 1 to 3) designed for the plastic substrate 112 of the present disclosure. Furthermore, Table 1 also lists the phase retardation (R0) and thickness H of several materials (Materials 4 to 7) that may not be used for the plastic substrate 112 of the present disclosure. The difference (birefringence, Δn) of every material is calculated using Eq. (1). The data show that values of the difference (birefringence, Δn) of Materials 1 to 3 range from 0 to 0.0001, whereas values of the difference (birefringence, Δn) of Materials 4 to 7 are obviously large and unable to improve the problem of dark-state light leakage. In general, the present disclosure selects materials with phase retardation (R0) within the range of 0 to 4.0 nm (for example, 0.5 nm or 0.6 nm) as the material for the plastic substrate 112.

TABLE 1

| | | Refractive | Refractive | | | |
|---|---|---|---|---|---|---|
| | Thickness | Index in | Index in | Difference | Phase | |
| | of Plastic | First | Second | (Birefrin- | Retardation | |
| | Substrate | Direction | Direction | gence, Δn) | (R0) | |
| Material 1 | 40 μm | 1.49999 | 1.49998 | 0.0000125 | 0.5 | nm |
| Material 2 | 40 μm | 1.49999 | 1.49998 | 0.000015 | 0.6 | nm |
| Material 3 | 40 μm | 1.4999 | 1.4998 | 0.0001 | 4.0 | nm |
| Material 4 | 50 μm | 1.6506 | 1.6769 | 0.0263 | 1315.0 | nm |
| Material 5 | 50 μm | 1.6515 | 1.6757 | 0.0242 | 1210.0 | nm |
| Material 6 | 36 μm | 1.6477 | 1.681 | 0.0333 | 1198.8 | nm |
| Material 7 | 36 μm | 1.6400 | 1.6829 | 0.0429 | 1544.4 | nm |

In one or more embodiments, the material used for the plastic substrate 112 may be polyethylene terephthalate (PET), cyclic olefin polymer (COP), colorless polyimide (CPI), triacetyl cellulose (TAC), polycarbonate (PC), poly methyl methacrylate (PMMA), or a combination thereof. Furthermore, polymer materials sold in the market, including polyimide (PI), cyclic olefin copolymer (COC), or polyvinyl alcohol (PVA), or materials that have suitable properties of high optical transparency (%), low haze (%), good thermal stability, and good mechanical properties may be used. For example, the transparency (%) greater than 92%, 93%, or 94%, the haze (%) smaller than 25%, 15%, 5%, or 0.5%, the good thermal stability when the temperature is higher in use, and the good mechanical properties such as, electrical properties, impact resistance, abrasion resistance, toughness, and hardness may be selected as the material made for the plastic substrate 112. Alternatively, biodegradable plastic films, such as acetylated cellulose polymers, may be used to produce the plastic substrate 112, taking into account environmental and social governance considerations. Through the adjustment of the difference (birefringence, Δn) and the thickness H of aforementioned materials, a plastic substrate 112 with a low phase retardation (R0) may be produced to solve dark-state light leakage problem. In the above-mentioned disclosure, an adjustments of the difference (birefringence, Δn) may be, for example, implemented by changing the direction, strength, temperature of the mechanical tensile applied during the material forming process, or by applying additional stress on the formed materials, or by adding nano-materials in the materials.

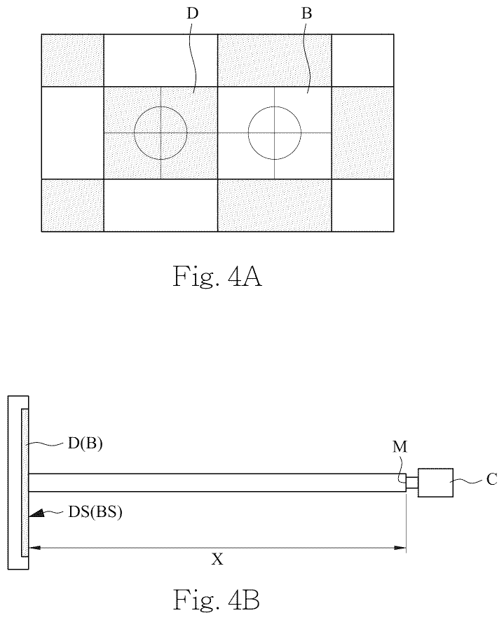

In general, when the difference (birefringence, Δn) and the thickness H of the material of the plastic substrate 112 are within the specified ranges of the present disclosure, the black level luminance of the touch display module 100 is 0.0001 cd/m² to 0.0005 cd/m², measured by black level testing. For example, the black level luminance of the touch display module 100 is 0.0002 cd/m², 0.0003 cd/m², or 0.0004 cd/m². In other words, the touch display module 100 is nearly free from difference (birefringence, Δn) and meets the testing standards for black-level luminance specified by the Video Electronics Standards Association (VESA™) for HDR 500 True Black™. For the measurement method of black level luminance of the touch display module 100, please refer to FIG. 4A and FIG. 4B, wherein FIG. 4A is a schematic diagram of the upward view of a window pattern of a checkerboard (black and white patches) displayed by the touch display module 100 according to several embodiments of the present disclosure. FIG. 4B is a schematic diagram of a setting for measuring the black level luminance of the touch display module 100 according to several embodiments of the present disclosure. The measurement method for determining the black level luminance of the present disclosure comprises the following steps. Step S1: activating the organic light-emitting diode display 120 (please refer to FIG. 3), and the touch display module 100 displays the bright state area B and the dark state area D in the checkerboard. The lengths of the display area occupied by the bright state area B and the dark state area D, respectively, in the horizontal direction, are 30-34%. The lengths of the display area occupied by the bright state area B and the dark state area D, respectively, in the vertical direction are 46-50%, as illustrated in FIG. 4A. Step S2: using a photometer C to measure the brightness (black level luminance) of the dark state area D. The vertical distance X between the measuring end M of the photometer C and the surface DS of the dark state area D is 50 cm. The aperture angle of the photometer is 2 degrees, as element marks (outside the brackets) in FIG. 4B.

On the other hand, the measurement methods for peak luminance and black level luminance of the aforementioned organic light-emitting diode display 120 of the present disclosure (please refer to FIG. 3) are similar, specifically comprising the following steps. Step S1′: Activate the organic light-emitting diode display 120. The touch display module 100 displays the bright state area B and the dark state area D in the checkerboard, wherein the bright state area B and the dark state area D, respectively, occupy 10% of the display area, as shown in FIG. 4A. Step S2′: using a photometer C to measure the peak luminance of the bright area B. The vertical distance X between the measuring end M of the photometer C and the surface BS of the bright state area B is 50 cm, and the aperture angle of photometer is 2 degrees, as element marks (within the brackets) in FIG. 4B.

Please refer to Table 2, which lists the optical properties (including phase retardation (R0) and mechanical properties) of several materials after adjusting the difference (birefringence, Δn) and thickness (10 μm). The present disclosure may determine which materials are selected for producing the plastic substrate 112 by comparing the phase retardation (R0) of each material, along with a comprehensive assessment of its other optical properties and mechanical properties.

TABLE 2

| | Material | Material | Material | Material | Material | Material |
|---|---|---|---|---|---|---|
| | 8 | 9 | 10 | 11 | 12 | 13 |
| | Optical Property | | | | | |
| Transparency | 91 | 93.5 | >90 | >91 | 93 | 93.8 |
| (%) | | | | | | |
| Haze | 0.5 | 0.11 | <1 | 0.10 | 0.08 | 0.78 |
| (%) | | | | | | |
| Refractive | 1.60 | 1.54 | No | 1.45-1.55 | 1.58 | 1.49 |
| Index | | | Measurement | | | |
| Phase | >1000 | <10 | 10-1000 | No | <10 | <10 |
| Retardation | | | | Measurement | | |
| (nm) | | | | | | |
| | Mechanical Property | | | | | |
| Tensile | 4.1 | 2.1 | >2 | 4.7 | 2.4 | 3.6 |
| Modulus | | | | | | |
| (GPa) | | | | | | |
| Tensile | >100 | <50 | <100 | 30 | 120 | <100 |
| Elongation | | | | | | |
| (%) | | | | | | |

Note:
Refractive index is the average value of the first refractive index and the second refractive index.

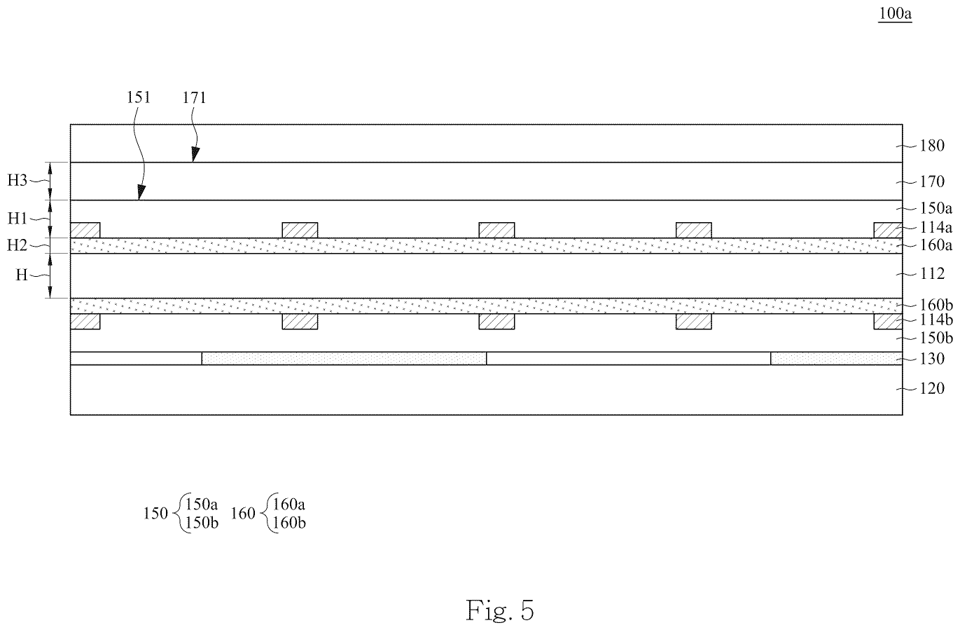

As shown in Table 1, to produce a plastic substrate 112 with an improved effect of dark-state light leakage being implemented, materials having a lower phase retardation (R0) of light rays, for example, Material 9, Material 12, and Material 13 that have a phase retardation (R0) smaller than 10 nm may be selected. To further consider the transparency and mechanical properties (such as tensile modulus) of the materials, Material 13 is selected for producing the plastic substrate 112. However, although materials with relatively lower phase retardation (R0) of light rays are used, a proper thickness H of suitable materials designed for the plastic substrate 112 is also required simultaneously to achieve the effect of reducing dark-state light leakage. Please refer to Table 3, which lists the optical properties of Materials 8, 12, and 13, made for the plastic substrate 112 with different thicknesses H. The data in Table 3 were measured using the touch display module 100a, as shown in FIG. 5. The structure of the touch display module 100a will be provided later.

TABLE 3

| | | | Optical Property | | |
|---|---|---|---|---|---|
| | | | Compar- | Compar- | |
| Dimension | Thick- | | ative | ative | Embodi- |
| of Touch | ness of | | Example 1 | Example 2 | ment1 |
| Display | Plastic | | (Material | (Material | (Material |
| Module | Substrate | Area | 8) | 12) | 13) |
| 13.4 inch | 0.038 | Peak | 501.4 | 507.4 | 502.5 |
| | Mm | Luminance | | | |
| | | of Bright | | | |
| | | State Area | | | |
| | | (nits) | | | |
| | | Black Level | 0.00222 | 0.00108 | 0.00041 |
| | | Luminance | | | |
| | | of Dark | | | |
| | | State Area | | | |
| | | (nits) | | | |
| 14.0 inch | 0.1 | Peak | No | No | 500.7 |
| | Mm | Luminance | Measure- | Measure- | |
| | | of Bright | ment | ment | |
| | | State Area | | | |
| | | (nits) | | | |
| | | Black Level | | | 0.00030 |
| | | Luminance | | | |
| | | of Dark | | | |
| | | State Area | | | |
| | | (nits) | | | |
| 16.0 inch | 0.04 | Peak | 502.4 | No | 503.0 |
| | Mm | Luminance | | Measure- | |
| | | of Bright | | ment | |
| | | State Area | | | |
| | | (nits) | | | |
| | | Black Level | 0.00131 | | 0.00024 |
| | | Luminance | | | |
| | | of Dark | | | |
| | | State Area | | | |
| | | (nits) | | | |

Note:
In Comparative Examples 1-2 and Embodiment 1, the thicknesses of optically clear adhesive layers are 0.075 mm, respectively (material to be silicon or acrylic); the thicknesses of primer coating layers are 0.01 to 5 μm, respectively (material to be resin); and the thicknesses of cover plates are 0.4 mm, respectively (material to be glass).

As shown in Table 3, since the phase retardation of Material 8 is too large, although the thickness thereof is relatively smaller, the black level luminance of Comparative Example 1 may not meet the standard for black level luminance specified by Video Electronics Standards Association (VESA™) for HDR 500 True Black™. Even though the phase retardation of Material 12 is relatively smaller, however, due to the thickness thereof being relatively larger, the black level luminance of Comparative Example 2 still may not satisfy the standard for black level luminance specified by Video Electronics Standards Association (VESA™) for HDR 500 True Black™. In contrast, in Embodiment 1, Material 13 has a phase retardation and thickness within a desired range. In other words, the Material 13 has the difference (birefringence, Δn) and thickness within a desired range. Therefore, the black level luminance of Embodiment 1 (Material 13) satisfies the required standard for black level luminance provided by Video Electronics Standards Association (VESA™) for HDR 500 True Black™. Please note that when the size of the touch display module gets smaller, due to the areas of the bright state area and the dark state area being respectively smaller, light rays may be easily transmitted from the bright state area to the dark state area relatively. Nevertheless, according to Embodiment 1, by taking into account the difference (birefringence, Δn) and thickness of the material, smaller touch display modules may still meet the required standard of black-level luminance.

Please refer to FIG. 1 and FIG. 3 again. In one or several embodiments, the touch display module 100 further comprises an optically clear adhesive layer 150. More specifically, the optically clear adhesive layer 150 of the touch display module 100 further comprises a first optically clear adhesive layer 150a and a second optically clear adhesive layer 150b. The first optically clear adhesive layer 150a is disposed on the first surface 111a of the plastic substrate 112 of the touch-sensing layer 110. The second optically clear adhesive layer 150b is disposed on the second surface 111b of the plastic substrate 112 of the touch-sensing layer 110. The transparency, contrast, and viewing angle of the touch display module 100 may be adjusted through the optically clear adhesive layer 150, as needed. Additionally, the optically clear adhesive layer 150 may provide structural support, prevent bubbles and defects, and enhance shock resistance and durability. In one or several embodiments, the optically clear adhesive layer 150 completely covers the electrode layer 114. Based on Snell's law, to ensure light rays are reflected by total reflection after penetrating the touch-sensing layer 110, the refractive index of the optically clear adhesive layer 150 is designed to be smaller than the refractive index of the plastic substrate 112. More specifically, the refractive index of the optically clear adhesive layer 150 is smaller than the average value of the first refractive index and the second refractive index of the plastic substrate 112. In more detail, the refractive index of the optically clear adhesive layer 150 ranges from 1.40 to 1.49. The material may be, for example, acrylic OCA (with a refractive index of 1.48 to 1.49) or silicon OCA (with a refractive index of 1.40 to 1.41). Since the material itself of the optically clear adhesive layer 150 has a smaller difference (birefringence, Δn), an impact from the thickness H1 of the optically clear adhesive layer 150 on the optical path is smaller, so the impact on the probability of having dark-state light leakage smaller.

Please refer to FIG. 5, which is a schematic diagram of a touch display module 100a viewed from the side, as shown in several other embodiments of the present disclosure. The difference between the touch display module 100a of FIG. 5 and the touch display module 100 of FIG. 1 is at least that the touch display module 100a further comprises a primer coating layer 160. More specifically, the touch display module 100a comprises a first primer coating layer 160a disposed on the first surface 111a of the plastic substrate 112 of the touch-sensing layer 110 and a second primer coating layer 160b disposed on the second surface 111b of the plastic substrate 112 of the touch-sensing layer 110. In one or several embodiments, the primer coating layer 160 is completely in contact with and covers the surface 111 of the plastic substrate 112. The primer coating layer 160 is disposed between the plastic substrate 112 and the electrode layer 114, for example, the first electrode layer 114a, or the second electrode layer 114b. The types of electrode layer 114 are not limited. The primer coating layer 160 is in contact with the lower surface 115 of the electrode layer 114, so that the electrode layer 114 may be firmly attached to the plastic substrate 112. Based on Snell's law, to ensure light rays are reflected by total reflection after penetrating the touch-sensing layer 110, the refractive index of the primer coating layer 160 is designed to be smaller than the refractive index of the plastic substrate 112. More specifically, the refractive index of the primer coating layer 160 is smaller than the average value of the first refractive index and the second refractive index of the plastic substrate 112. Please note that when the values of the refractive index of the optically clear adhesive layer 150 and the plastic substrate 112 are too close, it is less favorable for total reflection. The refractive index of the primer layer 160 may be designed to be smaller than the refractive index of the optical adhesive layer 150. In other embodiments, the difference between the refractive index of the primer 160 and the refractive index of the plastic substrate 112 is greater than the difference between the refractive index of the optical adhesive layer 150 and the refractive index of the plastic substrate 112. Therefore, the probability of total reflection may be increased. It may effectively solve the problem of dark-state light leakage. In more detail, the refractive index of the primer coating layer 160 is 1.37 to 1.39 (for example, 1.38). The material may be, for example, resin, polyester resin, alicyclic olefin resin, styrene resin, acrylic ester, polyvinylidene chloride (PVDC), materials with good moisture-blocking features (plastic substrate 112 made by different materials with different water absorption rates), materials with better adhesion to the plastic substrate 112, materials having anti-glare and anti-reflective features, or a combination thereof.

Since the material of the primer coating layer 160 itself has a larger difference (birefringence, Δn), the impact on the optical path from the thickness H2 of the primer coating layer 160 is greater. Therefore, designing the thickness H2 of the primer coating layer 160 to be within the aforementioned range may ensure that light rays in the primer coating layer 160 still have a low phase retardation (R0). The design ensures light rays have a tendency to propagate along the same optical path after leaving the plastic substrate 112 and may fulfill the effect of solving the problem of dark-state light leakage.

In one or several embodiments, the touch display module 100a further comprises a cover plate 170 and a surface treatment layer 180, disposed on the surface 151 of the first optically clear adhesive layer 150a that is facing away from the plastic substrate 112. The surface treatment layer 180 is disposed on the surface 171 of the cover plate 170 that is facing away from the plastic substrate 112. In one or several embodiments, the thickness H3 of the cover plate 170 is 0.2 mm to 2.0 mm (for example, 0.2 mm to 0.7 mm, 0.33 mm to 0.7 mm, 0.55 mm to 1.1 mm, or 1.1 mm to 2.0 mm), and the materials may be, for example, glass or ultra-thin glass (UTG). Generally, the thickness of ultra-thin glass is smaller than 0.2 mm, for example, 0.15 mm, 0.12 mm, 0.1 mm, or 0.03 mm. In one or several embodiments, the surface treatment layer 180 comprises an anti-glare layer (AG) produced by the method of chemical etching using hydrofluoric acid (HF) or other suitable materials, abrasive blasting technique, or spray coating. In other embodiments, the surface treatment layer 180 comprises an anti-reflective layer featured with destructive optical interference by arranging multiple layers of high refractive index layers and multiple layers of low refractive index layers periodically and stacked over mutually by using an optical-film plated method. In other embodiments, the surface treatment layer 180 comprises an anti-fingerprint (AF) layer formed through deposition of fluorine-containing materials, an anti-smudge (AS) layer, or a combination thereof. Since the cover plate 170 and the surface treatment layer 180 are comparatively away from the organic light-emitting diode display, the impact thereof on the optical path is lesser. Please note that elements not mentioned in FIG. 5 are the same as those corresponding numbered elements shown in FIG. 1 and, therefore, will not be repeated.

In one or more embodiments, the dark-state light leakage problem may be further solved by adjusting the surface properties of the plastic substrate 112. For example, by reducing the undulating degree and roughness degree of the surface 111 of the plastic substrate 112, lowering the photoelastic coefficient of the plastic substrate 112, and enhancing uniformity in the molecular arrangements of the material of the plastic substrate 112, the risk of light leakage may be reduced. For example, the arithmetic average roughness (Ra) of the surface of the plastic substrate 112 is controlled within the range of 2 Å to 200 Å. In one or more embodiments, the dark-state light leakage problem may be further solved by adjusting the materials of the electrode layer 114 or performing post-treatments on the electrode layer 114. For example, materials of the electrode layer 114 may be silver halide materials (such as silver bromide (AgBr), silver chloride (AgCl), silver iodide (AgI), or silver fluoride (AgF)) or electroless copper plating metal that have better light absorption made into the electrode layer 114, or the electrode layer 114 is treated by the blackening process. In several other embodiments, the dark-state light leakage problem may be further solved by adjusting the size of the electrode layer 114. For example, interference on the light rays may be reduced by reducing the linewidth of the electrode layer 114. For example, the linewidth of the electrode layer 114 is controlled within a range of 1.0 μm to 5.0 μm, preferably 1.2 μm to 3.5 μm, more preferably 1.7 μm to 3.0 μm. The linewidth of the electrode layer 114 may be controlled through various processes, including ink-jet printing, three-dimensional (3D) printing, transfer printing, screen printing, chemical plating, evaporation, sputtering, etched copper foil, atomic layer deposition (ALD), and photolithography.

According to the aforementioned embodiments of the present disclosure, by adjusting the thickness of the plastic substrate and controlling its difference (birefringence, Δn), light rays will experience low phase retardation as they penetrate the plastic substrate, thereby causing all light rays to tend to propagate along the same path through the plastic substrate. Hereby, most light rays are directly emitted from the bright state area, and the remaining small amount of light rays, not emitted from this area, undergo multiple instances of total reflection, which consumes energy. As a result, the probability that light rays are emitted from the dark state area is reduced so that the dark-state light leakage problem is solved.

The aforementioned embodiments are chosen to describe the present disclosure and are not intended to limit the scope of the present disclosure in any way. Alternative embodiments will become apparent to those skilled in the art to which the present disclosure pertains without departing from its spirit and scope. The scope of the present disclosure is defined by the appended claims rather than the foregoing descriptions and the exemplary embodiments described therein.

### Component Symbol

10: Touch display module
11: Touch-sensing layer
11a, 11b: Surface
12: Organic light-emitting diode (OLED) display
13: Light-shielding layer
14: Functional layer
50a: Detector
50b: Detector
100,100a: Touch display module
110: Touch-sensing layer
111: Surface
111a: First surface
111b: Second surface
112: Plastic substrate
114: Electrode layer
114a: First electrode layer
114b: Second electrode layer
115: Lower surface
120: Organic light-emitting diode (OLED) display
130: Light-shielding layer
150: Optically clear adhesive layer
150a: First optically clear adhesive layer
150b: Second optically clear adhesive layer
151: Surface
160: Primer coating layer
160a: First primer coating layer
160b: Second primer coating layer
170: Cover plate
171: Surface
180: Surface treatment layer
S1, S2: Side
B: Bright state area
BS: Surface
D: Dark state area
DS: Surface
C: Photometer
M: Measuring end
X: Vertical distance
H, H1, H2, H3: Thickness
La, Lb, Lc, L1, L2, L3: Light ray

What is claimed is:

1. A touch display module, comprising:
a touch-sensing layer, which comprises:
a plastic substrate, wherein a thickness of the plastic substrate is 10 μm to 400 μm, the plastic substrate has a first refractive index and a second refractive index in different directions, and a difference between the first refractive index and the second refractive index is 0 to 0.0001;
a first metal mesh electrode layer disposed on a first surface of the plastic substrate; and
a second metal mesh electrode layer disposed on a second surface of the plastic substrate, wherein the second surface faces away from the first surface; and
an organic light-emitting diode display disposed on one side of the touch-sensing layer, wherein a peak luminance of the organic light-emitting diode display is at least 390 nits;
wherein a maximum black level luminance of the touch display module is 0.0001 cd/m² to 0.0005 cd/m².

2. The touch display module of claim 1, wherein the thickness of the plastic substrate is 10 μm to 40 μm.

3. The touch display module of claim 1, wherein the difference between the first refractive index and the second refractive index is 0.0000125 to 0.0001.

4. The touch display module of claim 1, wherein the touch-sensing layer further comprises:
a primer coating layer disposed on the first surface of the plastic substrate, wherein the first surface faces away from the one side of the touch-sensing layer, and a refractive index of the primer coating layer is smaller than an average value of the first refractive index and the second refractive index.

5. The touch display module of claim 4, wherein the primer coating layer is disposed between the plastic substrate and the first metal mesh electrode layer.

6. The touch display module of claim 1, further comprising:
an optically clear adhesive layer disposed on the first surface of the plastic substrate, wherein the first surface faces away from the one side of the touch-sensing layer, and a refractive index of the optically clear adhesive layer is smaller than an average value of the first refractive index and the second refractive index.

7. A display module, comprising:
a plastic substrate, wherein a thickness of the plastic substrate is 10 μm to 400 μm, the plastic substrate has a first refractive index and a second refractive index in different directions, and a difference between the first refractive index and the second refractive index is 0 to 0.0001; and
an organic light-emitting diode display disposed on one side of the plastic substrate, wherein a peak luminance of the organic light-emitting diode display is at least 390 nits;
wherein a maximum black level luminance of the display module is 0.0001 cd/m² to 0.0005 cd/m².

8. The display module of claim 7, wherein the thickness of the plastic substrate is 10 μm to 40 μm.

9. The display module of claim 7, wherein the difference between the first refractive index and the second refractive index is 0.0000125 to 0.0001.

10. The display module of claim 7, wherein a surface roughness of the plastic substrate is 2 Å to 200 Å.

11. The display module of claim 7, further comprising:
an optically clear adhesive layer disposed on a surface facing away from the one side of the plastic substrate, wherein a refractive index of the optically clear adhesive layer is smaller than an average value of the first refractive index and the second refractive index.

12. The display module of claim 11, further comprising:
a primer coating layer disposed between the plastic substrate and the optically clear adhesive layer, wherein a refractive index of the primer coating layer is smaller than the average value of the first refractive index and the second refractive index.

13. The display module of claim 12, wherein the refractive index of the primer coating layer is smaller than the refractive index of the optically clear adhesive layer.

14. The display module of claim 13, wherein a difference between the refractive index of the primer coating layer and an average value of the refractive index of the plastic substrate is larger than a difference between the refractive index of the optically clear adhesive layer and the average value of the refractive index of the plastic substrate.

15. The display module of claim 12, wherein a thickness of the primer coating layer is 0.01 μm to 5 μm.

16. A touch display module, comprising:
a touch-sensing layer, which comprises:
a plastic substrate, wherein a thickness of the plastic substrate is 10 μm to 400 μm, the plastic substrate has a first refractive index and a second refractive index in different directions, and a difference between the first refractive index and the second refractive index is 0 to 0.0001;
a first touch electrode layer disposed on an upper surface or a lower surface of the plastic substrate; and
a second touch electrode layer disposed on the upper surface or the lower surface of the plastic substrate; and
an organic light-emitting diode display disposed on one side of the touch-sensing layer, wherein a peak luminance of the organic light-emitting diode display is at least 390 nits;
wherein a maximum black level luminance of the touch display module is 0.0001 cd/m² to 0.0005 cd/m².

17. The touch display module of claim 16, wherein the thickness of the plastic substrate is 10 μm to 40 μm.

18. The touch display module of claim 16, wherein the difference between the first refractive index and the second refractive index is 0.0000125 to 0.0001.

19. The touch display module of claim 16, wherein the touch-sensing layer further comprises:
two primer coating layers disposed on the upper surface and the lower surface of the plastic substrate, wherein refractive indices of the two primer coating layers are smaller than an average value of the first refractive index and the second refractive index.

20. The touch display module of claim 16, further comprising:
two optically clear adhesive layers respectively disposed on the upper surface and the lower surface of the plastic substrate wherein refractive indices of the two optically clear adhesive layers are smaller than an average value of the first refractive index and the second refractive index.
